(19) United States
(12) Patent Application Publication
(10) Pub. No.: US 2022/0367234 A1
(43) Pub. Date: Nov. 17, 2022

(54) DICING DIE ATTACH FILM AND METHOD OF PRODUCING THE SAME, AND SEMICONDUCTOR PACKAGE AND METHOD OF PRODUCING THE SAME

(71) Applicant: FURUKAWA ELECTRIC CO., LTD., Tokyo (JP)

(72) Inventors: Yota OTANI, Tokyo (JP); Hiromitsu MARUYAMA, Tokyo (JP); Minoru MORITA, Tokyo (JP)

(73) Assignee: FURUKAWA ELECTRIC CO., LTD., Tokyo (JP)

(21) Appl. No.: 17/872,568

(22) Filed: Jul. 25, 2022

Related U.S. Application Data
(63) Continuation of application No. PCT/JP2022/009903, filed on Mar. 8, 2022.

(30) Foreign Application Priority Data
Mar. 26, 2021 (JP) 2021-052761

(51) Int. Cl. H01L 21/683; H01L 23/00

(52) U.S. Cl. CPC H01L 21/6836; H01L 24/27; H01L 24/29; H01L 24/73; H01L 24/83; H01L 2221/68327; H01L 2224/27436; H01L 2224/2919; H01L 2924/0665; H01L 2224/73265; H01L 2224/83862; H01L 2224/83204

(57) ABSTRACT

A dicing die attach film including a dicing film and a die attach film laminated on the dicing film, in which
the die attach film has an arithmetic average roughness Ra1 of from 0.05 to 2.50 μm at a surface in contact with the dicing film, and
a value of ratio of Ra1 to an arithmetic average roughness Ra2 at a surface that is of the die attach film and is opposite to the surface in contact with the dicing film is from 1.05 to 28.00.

### CROSS-REFERENCE TO RELATED APPLICATIONS

This application is a Continuation of PCT International Application No. PCT/JP2022/009903 filed on Mar. 8, 2022, which claims priority under 35 U.S.C. § 119 (a) to Japanese Patent Application No. 2021-052761 filed in Japan on Mar. 26, 2021. Each of the above applications is hereby expressly incorporated by reference, in its entirely, into the present application.

### FIELD OF THE INVENTION

The present invention relates to a dicing die attach film and a method of producing the same, and a semiconductor package and a method of producing the same.

### BACKGROUND OF THE INVENTION

Stacked MCPs (Multi Chip Package) in which semiconductor chips are multistacked have recently been widely spread. Such stacked MCPs are mounted on memory packages for mobile phones or portable audio devices. Further, along with multi-functionality of mobile phones and the like, high densification and high integration of the package have also been advanced. Along with such advance, multistacking of the semiconductor chips has been advanced.

Film-like adhesives (die attach films, die bond films) have been used for bonding a circuit board and a semiconductor chip or bonding semiconductor chips in the production process of such a memory package. Along with multistacking of the chips, reduction in thickness of the die attach film has also been increasingly required. Also, with miniaturization in a wiring rule of the wafer, heat is more likely to be generated on the surface of the semiconductor element. Therefore, in order to release the heat to the outside of the package, these die attach films have been required to have high thermal conductivity.

For example, Patent Literature 1 describes a thermosetting die bond film characterized by containing thermally conductive particles having a thermal conductivity of 12 W/m·K or more in an amount of 75 wt % or more based on the entire thermosetting die bond film, and having a surface roughness Ra of 200 nm or less at one surface. According to the technology described in Patent Literature 1, it is considered that the peeling strength at the time of peeling from the laminated state on the dicing sheet can be stabilized while the thermosetting die bond film is highly filled with the thermally conductive particles.

Patent Literature 2 describes a multilayer resin sheet that includes: a resin composition layer that includes a thermosetting resin and a filler; and an adhesive layer that is disposed on at least one surface of the resin composition layer, the adhesive layer having an arithmetic average surface roughness Ra of 1.5 μm or less at a surface that does not face the resin composition layer.

### CITATION LIST

### Patent Literature

Patent Literature 1: JP-A-2015-103580 (“JP-A” means an unexamined published Japanese patent application)
Patent Literature 2: JP-A-2019-014261

### SUMMARY OF THE INVENTION

### Technical Problem

One of die attach film surfaces of a die attach film is usually attached to a semiconductor wafer; the other surface is tightly adhered to a dicing film; the semiconductor wafer is diced using the dicing film as a base to prepare semiconductor chips; each semiconductor chip with the die attach film is peeled (picked up) from the dicing film by using a pickup collet on a die bonder; then, the semiconductor chip is subject to thermocompression bonding to mount the semiconductor chip on a circuit board via the die attach film.

The pickup collet stores heat during the thermocompression bonding, and the heat storage amount increases as the thermocompression bonding is repeated. When the next semiconductor chip is mounted in such a state, heat is transferred to the interface with the dicing film through the die attach film. As a result, there is a problem that part of the die attach film tends to remain on the dicing film at the time of pickup (what is called a pickup failure). This problem tends to become more apparent as the thermal conductivity of the die attach film increases.

The present invention provides a dicing die attach film including a dicing film and a die attach film laminated on the dicing film, wherein a pickup failure is less likely to occur even when a pickup collet stores heat at the pickup step during production of a semiconductor device. Further, the present invention provides a method of producing the dicing die attach film, and a semiconductor package with the dicing die attach film and a method of producing the same.

### Solution to Problem

The present inventors have conducted intensive research in view of the above problems, and, as a result, have found that by controlling the surface roughness of a bonding surface between a die attach film and a dicing film and the surface roughness of a bonding surface between the die attach film and a semiconductor wafer to have a specific relationship, a dicing die attach film that is less likely to cause any pickup failure can be obtained. The present invention is based on these findings, and after further investigation, has been completed.

The above problems of the present invention have been solved by the following means.

[1]

A dicing die attach film, including:

a dicing film; and

a die attach film laminated on the dicing film,

wherein the die attach film has an arithmetic average roughness Ra1 of from 0.05 to 2.50 μm at a surface in contact with the dicing film, and
wherein a value of ratio of Ra1 to an arithmetic average roughness Ra2 at a surface that is of the die attach film and is opposite to the surface in contact with the dicing film is from 1.05 to 28.00.
[2]

The dicing die attach film described in [1],

wherein the die attach film includes:

an epoxy resin (A),

an epoxy resin curing agent (B),

a polymer component (C), and

an inorganic filler (D), and

wherein the die attach film is thermally cured to give a cured body having a thermal conductivity of 1.0 W/m·K or more.
[3]

The dicing die attach film described in [1] or [2], wherein when the die attach film is heated at a temperature elevation rate of 5° C./min from 25° C., a melt viscosity at 120° C. is in a range of 500 to 10,000 Pa·s.

[4]

The dicing die attach film described in any one of [1] to [3], wherein the dicing film is energy ray-curable.

[5]

A method of producing the dicing die attach film described in any one of [1] to [4], including leveling a surface of the die attach film by using a pressure roll to create a surface state satisfying Ra1 and Ra2.

[6]

A semiconductor package, including:

a semiconductor chip and a circuit board which are bonded to each other with a thermally cured product of a bonding agent; and/or

semiconductor chips which are bonded to each other with a thermally cured product of a bonding agent,

wherein the bonding agent is derived from the die attach film of the dicing die attach film described in any one of [1] to [4].
[7]

A method of producing a semiconductor package, including the steps of:

a first step of thermocompression bonding the dicing die attach film described in any one of [1] to [4] to a back surface of a semiconductor wafer where at least one semiconductor circuit is formed on a surface so that the die attach film is in contact with the back surface of the semiconductor wafer;

a second step of integrally dicing the semiconductor wafer and the die attach film to obtain a semiconductor chip with a bonding agent layer on the dicing film, the semiconductor chip with a bonding agent layer including a piece of the die attach film and a semiconductor chip;

a third step of removing the semiconductor chip with a bonding agent layer from the dicing film and thermocompression bonding the semiconductor chip with a bonding agent layer and a circuit board via the bonding agent layer; and

a fourth step of thermally curing the bonding agent layer.

The numerical ranges indicated with the use of the term “to” in the present invention refer to ranges including the numerical values before and after the term “to” respectively as the lower limit and the upper limit.

In the present invention, (meth)acryl means either or both of acryl and methacryl. The same applies to (meth)acrylate.

In the present invention, the terms “upper” and “lower” with respect to the dicing die attach film are used for convenience such that the dicing film side is “lower” and the die attach film side is “upper”.

### Advantageous Effects of Invention

A dicing die attach film in the present invention includes a dicing film and a die attach film laminated on the dicing film, wherein a pickup failure is less likely to occur even when a pickup collet stores heat at the pickup step during production of a semiconductor device. The method of producing a dicing die attach film according to the present invention is a method suitable for obtaining the dicing die attach film of the present invention as described above. In addition, a semiconductor package of the present invention can be produced using the dicing die attach film of the present invention, and a good product yield excels because a pickup failure is unlikely to occur during the production process. Further, according to the method of producing the semiconductor package of the present invention, a pickup failure is unlikely to occur during the production process, so that the yield of the semiconductor package can be effectively increased.

### BRIEF DESCRIPTION OF DRAWINGS

FIG. 1 is a schematic longitudinal cross-sectional view illustrating a preferred embodiment of a first step of a method of producing a semiconductor package of the present invention.

FIG. 2 is a schematic longitudinal cross-sectional view illustrating a preferred embodiment of a second step of a method of producing a semiconductor package of the present invention.

FIG. 3 is a schematic longitudinal cross-sectional view illustrating a preferred embodiment of a third step of a method of producing a semiconductor package of the present invention.

FIG. 4 is a schematic longitudinal cross-sectional view illustrating a preferred embodiment of a step of connecting a bonding wire of a method of producing a semiconductor package of the present invention.

FIG. 5 is a schematic longitudinal cross-sectional view illustrating an example of an embodiment of multistacking of a method of producing a semiconductor package of the present invention.

FIG. 6 is a schematic longitudinal cross-sectional view illustrating an example of an embodiment of another multistacking of a method of producing a semiconductor package of the present invention.

FIG. 7 is a schematic longitudinal cross-sectional view illustrating a preferred embodiment of a semiconductor package produced by a method of producing a semiconductor package of the present invention.

### DESCRIPTION OF EMBODIMENTS

### [Dicing Die Attach Film]

A dicing die attach film of the present invention includes a dicing film (temporary-adhesive film) and a die attach film (bonding agent film) stacked on this dicing film. The dicing film and the die attach film are in contact with each other. The dicing die attach film of the present invention can be in the form in which a dicing film and a die attach film in this order are provided on a base material (also referred to as a substrate film). In addition, a release film, for instance, may be provided on the die attach film.

The case of simply being referred to as the “dicing film” in the present invention, by itself, means a film including, as a component, a temporary-adhesive. That is, when the dicing film has a laminated structure with a substrate film and/or a release film (release liner, releasing film), these substrate film and release film are regarded as another constituent layer different from the dicing film. The dicing film itself or a layer formed using the dicing film may be referred to as a temporary-adhesive layer.

Likewise, the case of simply being referred to as the “die attach film” in the present invention, by itself, means a film including, as a component, a bonding agent. That is, when the die attach film has a laminated structure with a substrate film and/or a release film, these substrate film and release film are regarded as another constituent layer different from the die attach film. A die attach film itself or a layer formed using the die attach film may be referred to as a bonding agent layer.

On the other hand, in the present invention, the term “dicing die attach film” is used in the sense of including all forms that can be distributed in the market as a product. That is, the present invention is not limited to the laminate having a two-layer structure including the dicing film and the die attach film laminated on the dicing film, and as described above, when the substrate film and/or the release film are layered on the dicing film and/or the die attach film, the entire layered structure is regarded as a “dicing die attach film”.

In the dicing die attach film of the present invention, the surface roughness of the die attach film is controlled. That is, in the die attach film, the arithmetic average roughness Ra (referred to as Ra1) at a surface in contact with the dicing film is controlled to have a constant roughness in the range of 0.05 to 2.50 μm, and the value of ratio (Ra1/Ra2) of Ra1 to an arithmetic average roughness Ra (referred to as Ra2) at a surface opposite to the surface that is in contact with the dicing film of the die attach film is controlled to be in the range of 1.05 to 28.00. By controlling each surface roughness of the die attach film as described above, the die attach film should be unlikely to remain on the dicing film in the pickup step after the dicing step during production of a semiconductor device (semiconductor package). As a result, the diced die attach film piece (bonding agent layer) can be peeled off from the dicing film while integrally having the diced semiconductor chip, and bonding defects such as generation of voids can be suppressed in subsequent mounting of each semiconductor chip on a circuit board.

Ra1 is preferably 0.08 μm or more, more preferably 0.10 μm or more, and still more preferably 0.12 μm or more from the viewpoint of more effectively preventing a pickup failure. From the viewpoint of further enhancing adhesion to the dicing film at the time of dicing, Ra1 is preferably 2.30 μm or less, more preferably 2.20 μm or less, and still more preferably 2.10 μm or less, or also preferably 2.00 μm or less. Thus, Ra1 is preferably from 0.08 to 2.30 μm, more preferably from 0.10 to 2.20 μm, still more preferably from 0.12 to 2.10 μm, and still more preferably from 0.12 to 2.00 μm.

Ra2 is usually 0.03 μm or more, and may be 0.05 μm or more, 0.06 μm or more, or 0.07 μm or more. From the viewpoint of adhesion to a wafer, Ra2 is preferably 2.00 μm or less, more preferably 1.50 μm or less, still more preferably 1.00 μm or less, still more preferably 0.50 μm or less, and still more preferably 0.30 μm or less, or also preferably 0.20 μm or less, also preferably 0.16 μm or less, also preferably less than 0.10 μm, also preferably 0.095 μm or less, and also preferably 0.09 μm or less. Thus, Ra2 is preferably from 0.03 to 2.00 μm, also preferably from 0.05 to 1.50 μm, also preferably from 0.06 to 1.00 μm, also preferably from 0.07 to 0.50 μm, also preferably from 0.07 to 0.30 μm, also preferably from 0.07 to 0.20 μm, and also preferably from 0.07 to 0.16 μm. In addition, from the viewpoint of suppressing generation of voids at the time of bonding to a wafer in order to further improve wafer adhesion, Ra2 is preferably 0.05 μm or more and less than 0.10 μm, also preferably from 0.05 to 0.095 μm, and also preferably from 0.06 to 0.09 μm.

The value of ratio of Ra1 to Ra2 (Ra1/Ra2) is preferably 1.06 or more and more preferably 1.08 or more, or also preferably 1.10 or more, also preferably 1.50 or more, also preferably 2.00 or more, also preferably 2.50 or more, also preferably 4.50 or more, also preferably 8.20 or more, and also preferably 10.10 or more from the viewpoint of more effectively suppressing a pickup failure. In addition, Ra1/Ra2 is preferably 25.00 or less, more preferably 20.00 or less, and still more preferably 18.00 or less, or also preferably 15.00 or less, and also preferably 12.00 or less from the viewpoint of more reliably securing sufficient adhesion to the dicing film at the time of dicing. Thus, Ra1/Ra2 is preferably from 1.06 to 25.00, more preferably from 1.08 to 20.00, and still more preferably from 1.10 to 18.00, or also preferably from 1.50 to 15.00, also preferably from 2.00 to 12.00, and also preferably from 2.50 to 12.00. Ra1/Ra2 may be from 4.50 to 27.00 and preferably from 8.20 to 27.00 or preferably from 10.10 to 27.00.

Hereinafter, when simply referred to as “surface roughness”, it means arithmetic average roughness. This arithmetic average roughness may be determined by the method described in Examples described later.

In the dicing die attach film of the present invention, the above die attach film preferably contains an epoxy resin (A), an epoxy resin curing agent (B), a polymer component (C), and an inorganic filler (D). Each component will be described in this order.

### <Epoxy Resin (A)>

The epoxy resin (A) is a thermosetting resin having an epoxy group, and has an epoxy equivalent of 500 g/eq or less. The epoxy resin (A) may be liquid, solid, or semi-solid. The liquid in the present invention means that the softening point is less than 25° C. The solid means that the softening point is 60° C. or more. The semi-solid means that the softening point is between the softening point of the liquid and the softening point of the solid (25° C. or more and less than 60° C.). The softening point of the epoxy resin (A) used in the present invention is preferably 100° C. or less from the viewpoint of obtaining a die attach film that can reach low melt viscosity in a preferable temperature range (e.g., 60 to 120° C.). Incidentally, in the present invention, the softening point is a value measured by the ASTM protocol (measurement condition: in accordance with ASTM D6090-17).

In the epoxy resin (A) used in the present invention, the epoxy equivalent is preferably 150 to 450 g/eq from the viewpoint of increasing the crosslinking density of a cured product, and as a result, increasing the contact ratio between blended inorganic fillers (D) and the contact area between inorganic fillers (D), thus providing higher thermal conductivity. Incidentally, in the present invention, the epoxy equivalent refers to the number of grams of a resin containing 1 gram equivalent of epoxy group (g/eq).

The mass average molecular weight of the epoxy resin (A) is usually preferably less than 10,000 and more preferably 5,000 or less. The lower limit is not particularly limited, but is practically 300 or more.

The mass average molecular weight is a value obtained by GPC (Gel Permeation Chromatography) analysis.

Examples of the skeleton of the epoxy resin (A) include a phenol novolac type, an orthocresol novolac type, a cresol novolac type, a dicyclopentadiene type, a biphenyl type, a fluorene bisphenol type, a triazine type, a naphthol type, a naphthalene diol type, a triphenylmethane type, a tetraphenyl type, a bisphenol A type, a bisphenol F type, a bisphenol AD type, a bisphenol S type, and a trimethylolmethane type. Among them, a triphenylmethane type, a bisphenol A type, a cresol novolac type, and an orthocresol novolac type are preferable from the viewpoint of being capable of obtaining a die attach film having low resin crystallinity and good appearance.

The content of the epoxy resin (A) in the die attach film is preferably from 3 to 70 mass %, preferably from 3 to 30 mass %, and more preferably from 5 to 30 mass %. By setting the content within the above preferable range, it is possible to enhance die attach performance while suppressing the formation of any jig mark. Meanwhile, by adjusting the content to the preferable upper limit or less, generation of oligomer components can be suppressed, and the state of the film (e.g., film tack property) is unlikely to be changed in the case of a small change in temperature.

### <Epoxy Resin Curing Agent (B)>

As the epoxy resin curing agent (B), optional curing agents such as amines, acid anhydrides, and polyhydric phenols can be used. In the present invention, a latent curing agent is preferably used from the viewpoint of having a low melt viscosity, and being capable of providing a die attach film that exhibits curability at a high temperature more than a certain temperature, has rapid curability, and further has high storage stability that enables long-term storage at room temperature.

Examples of the latent curing agent include a dicyandiamide compound, an imidazole compound, a curing catalyst-complex polyhydric phenol compound, a hydrazide compound, a boron trifluoride-amine complex, an aminimide compound, a polyamine salt, and modified products or microcapsules thereof. They may be used singly, or in combination of two or more types thereof. Use of an imidazole compound is more preferable from the viewpoint of providing even better latency (properties of excellent stability at room temperature and exhibiting curability by heating) and providing a more rapid curing rate.

The content of the epoxy resin curing agent (B) based on 100 parts by mass of the epoxy resin (A) is preferably from 0.5 to 100 parts by mass, more preferably from 1 to 80 parts by mass, further preferably from 2 to 50 parts by mass, and further preferably from 4 to 20 parts by mass. Setting the content to the preferable lower limit or more can further reduce the curing time, while setting the content to the preferable upper limit or less can prevent the excess curing agent from remaining in the die attach film. As a result, moisture absorption by the remaining curing agent can be suppressed, and thus the reliability of the semiconductor device can be improved.

### <Polymer Component (C)>

The polymer component (C) has only to be a component that suppresses a film tack property at normal temperature (25° C.) (property that the film state is likely to change by even a little temperature change) and imparts sufficient adhesiveness and film formability (film forming property) when the die attach film is formed. Examples thereof include natural rubber, butyl rubber, isoprene rubber, chloroprene rubber, an ethylene-vinyl acetate copolymer, an ethylene-(meth)acrylic acid copolymer, an ethylene-(meth)acrylic acid ester copolymer, polybutadiene resin, polycarbonate resin, thermoplastic polyimide resin, polyamide resins such as 6-nylon and 6,6-nylon, phenoxy resin, (meth)acrylic resin, polyester resins such as polyethylene terephthalate and polybutylene terephthalate, polyamideimide resin, fluororesin, and the like. These polymer components (C) may be used singly, or in combination of two or more types thereof.

The mass average molecular weight of the polymer component (C) is usually 10,000 or more. The upper limit is not particularly limited, but is practically 5,000,000 or less.

The mass average molecular weight of the polymer component (C) is a value determined by GPC (Gel Permeation Chromatography) in terms of polystyrene. Hereinafter, the value of the mass average molecular weight of the specific polymer component (C) has the same meaning.

The glass transition temperature (Tg) of the polymer component (C) is preferably less than 100° C., and more preferably less than 90° C. The lower limit is preferably −30° C. or higher, preferably 0° C. or higher, and more preferably 10° C. or higher.

The glass transition temperature of the polymer component (C) is a glass transition temperature measured by DSC at a temperature elevation rate of 0.1° C./min. Hereinafter, the value of the glass transition temperature of the specific polymer component (C) has the same meaning.

Note that, in the present invention, with regard to the epoxy resin (A) and a resin which can have an epoxy group such as phenoxy resin among the polymer component (C), a resin having an epoxy equivalent of 500 g/eq or less is classified into the epoxy resin (A) and a resin which does not correspond to the above resin is classified into the component (C).

It is preferable to use at least one kind of phenoxy resin as the polymer component (C), and it is also preferable that the polymer component (C) is a phenoxy resin. The phenoxy resin has a structure similar to that of the epoxy resin (A), and thus has favorable compatibility with the epoxy resin (A). The phenoxy resin has low resin melt viscosity and exhibits excellent effect on adhesiveness. Also, the phenoxy resin has high heat resistance and small saturated water absorption, and thus is preferable from the viewpoint of ensuring the reliability of the semiconductor package. Further, the phenoxy resin is preferable in view of eliminating a tack property and brittleness at normal temperature.

The phenoxy resin can be obtained by a reaction of a bisphenol or biphenol compound with epihalohydrin such as epichlorohydrin, or a reaction of liquid epoxy resin with a bisphenol or biphenol compound.

In any of the reactions, the bisphenol or biphenol compound is preferably a compound represented by the following Formula (A).

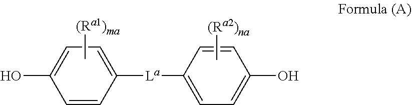

In Formula (A), L^{a} represents a single bond or divalent linking group, and R^{a1} and R^{a2} each independently represents a substituent. ma and na each independently represents an integer of 0 to 4.

In L^{a}, a divalent linking group is preferably an alkylene group, a phenylene group, —O—, —S—, —SO—, —SO₂—, or a group in which an alkylene group and a phenylene group are combined.

The number of carbon atoms of the alkylene group is preferably 1 to 10, more preferably 1 to 6, further preferably 1 to 3, particularly preferably 1 or 2, and most preferably 1.

The alkylene group is preferably —C(R^{α})(R^{β})—, and here, R^{α} and R^{β} each independently represent a hydrogen atom, an alkyl group, and an aryl group. R^{α} and R^{β} may be bonded to each other to form a ring. R^{α} and R^{β} are preferably a hydrogen atom or an alkyl group (for example, methyl, ethyl, isopropyl, n-propyl, n-butyl, isobutyl, hexyl, octyl, and 2-ethylhexyl). The alkylene group is, in particular, preferably —CH₂—, —CH(CH₃)—, or C(CH₃)₂—, more preferably —CH₂— or —CH(CH₃)—, and further preferably —CH₂—.

The number of carbon atoms of the phenylene group is preferably 6 to 12, more preferably 6 to 8, and even more preferably 6. Examples of the phenylene group include p-phenylene, m-phenylene, or o-phenylene, among which p-phenylene and m-phenylene are preferable.

The group in which an alkylene group and a phenylene group are combined is preferably an alkylene-phenylene-alkylene group, and more preferably —C(R^{α})(R^{β})-phenylene-C(R^{α})(R^{β})—.

The ring formed by bonding of R^{α} and R^{β} is preferably a 5- or 6-membered ring, more preferably a cyclopentane ring or a cyclohexane ring, and even more preferably a cyclohexane ring.

L^{a} is preferably a single bond, an alkylene group, —O—, or —SO₂—; and more preferably an alkylene group.

R^{a1} and R^{a2} are preferably an alkyl group, an aryl group, an alkoxy group, an alkylthio group, or a halogen atom; more preferably an alkyl group, an aryl group, or a halogen atom; and further preferably an alkyl group.

ma and na are preferably 0 to 2, more preferably 0 or 1, and even more preferably 0.

Examples of the bisphenol or biphenol compound include bisphenol A, bisphenol AD, bisphenol AP, bisphenol AF, bisphenol B, bisphenol BP, bisphenol C, bisphenol E, bisphenol F, bisphenol G, bisphenol M, bisphenol S, bisphenol P, bisphenol PH, bisphenol TMC, bisphenol Z, 4,4′-biphenol, 2,2′-dimethyl-4,4′-biphenol, 2,2′,6,6′-tetramethyl-4,4′-biphenol, cardo skeleton type bisphenol, and the like. Bisphenol A, bisphenol AD, bisphenol C, bisphenol E, bisphenol F, and 4,4′-biphenol are preferable; bisphenol A, bisphenol E, and bisphenol F are more preferable; and bisphenol A is particularly preferable.

The liquid epoxy resin is preferably diglycidyl ether of an aliphatic diol compound, and is more preferably a compound represented by the following Formula (B).

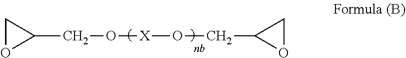

In Formula (B), X represents an alkylene group, and nb represents an integer of 1 to 10.

The number of carbon atoms of the alkylene group is preferably 2 to 10, more preferably 2 to 8, further preferably 3 to 8, particularly preferably 4 to 6, and most preferably 6.

Examples of the alkylene group include ethylene, propylene, butylene, pentylene, hexylene, and octylene. Ethylene, trimethylene, tetramethylene, pentamethylene, heptamethylene, hexamethylene, or octamethylene is preferable.

nb is preferably 1 to 6, more preferably 1 to 3, and even more preferably 1.

Here, when nb is 2 to 10, X is preferably ethylene or propylene, and even more preferably ethylene.

Examples of the aliphatic diol compound in diglycidyl ether include ethylene glycol, propylene glycol, diethylene glycol, triethylene glycol, polyethylene glycol, 1,3-propanediol, 1,4-butanediol, 1,5-heptanediol, 1,6-hexanediol, 1,7-pentanediol, and 1,8-octanediol.

In the above reaction, the phenoxy resin may be a phenoxy resin obtained by reacting a single bisphenol or biphenol compound, or aliphatic diol compound, or a phenoxy resin obtained by mixing and reacting two or more types of bisphenol or biphenol compound, or aliphatic diol compound. For example, a reaction of diglycidyl ether of 1,6-hexanediol with a mixture of bisphenol A and bisphenol F is exemplified.

The phenoxy resin (C) in the present invention is preferably a phenoxy resin obtained by a reaction of a liquid epoxy resin with a bisphenol or biphenol compound, and more preferably a phenoxy resin having a repeating unit represented by the following Formula (1).

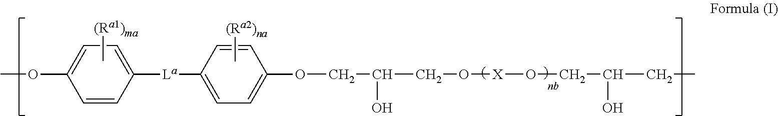

In the formula (1), L^{a}, R^{a1}, R^{a2}, ma, and na are synonymous with L^{a}, R^{a1}, R^{a2}, ma, and na, respectively, in the formula (A), and the preferable ranges are also the same. X and nb have the same meanings as those in Formula (B), and the preferable ranges are also the same.

In the present invention, a polymer of bisphenol A and diglycidyl ether of 1,6-hexanediol is preferable among these substances.

Now, focusing on the skeleton of the phenoxy resin, in the present invention, a bisphenol A-type phenoxy resin or a bisphenol A-F type copolymerized phenoxy resin may be preferably used. In addition, a low-elastic high-heat-resistant phenoxy resin may be preferably used.

The mass average molecular weight of the phenoxy resin (C) is preferably 10,000 or larger and more preferably from 10,000 to 100,000.

Further, the amount of epoxy group remaining in a small amount in the phenoxy resin (C) is preferably more than 5,000 g/eq in epoxy equivalent amount.

The glass transition temperature (Tg) of the phenoxy resin (C) is preferably less than 100° C., and more preferably less than 90° C. The lower limit is preferably 0° C. or higher and more preferably 10° C. or higher.

The phenoxy resin (C) may be synthesized by the above method, or a commercially available product may be used. Examples of the commercially available product include 1256 (bisphenol A type phenoxy resin, manufactured by Mitsubishi Chemical Corporation), YP-50 (bisphenol A type phenoxy resin, manufactured by NSCC Epoxy Manufacturing Co., Ltd.), YP-70 (bisphenol A/F type phenoxy resin, manufactured by NSCC Epoxy Manufacturing Co., Ltd.), FX-316 (bisphenol F type phenoxy resin, manufactured by NSCC Epoxy Manufacturing Co., Ltd.), FX-280S (cardo skeleton type phenoxy resin, manufactured by NSCC Epoxy Manufacturing Co., Ltd.), 4250 (bisphenol A type/F type phenoxy resin, manufactured by Mitsubishi Chemical Corporation), and FX-310 (low-elastic high-heat-resistant phenoxy resin, manufactured by NSCC Epoxy Manufacturing Co., Ltd.).

It is also preferable to use at least one kind of (meth)acrylic resin as the polymer component (C), and it is also preferable that the polymer component (C) is a (meth)acrylic resin. As the (meth)acrylic resin, a resin composed of a (meth)acrylic copolymer, which is known to be applicable to a die attach film, is used.

The mass average molecular weight of the (meth)acrylic copolymer is preferably 10,000 to 2,000,000, and more preferably 100,000 to 1,500,000. By adjusting the mass average molecular weight to a level within the preferable range, a tack property can be reduced and increase in the melt viscosity can also be suppressed.

The glass transition temperature of the (meth)acrylic copolymer is preferably in a range of −10° C. to 50° C., more preferably 0° C. to 40° C., and further preferably 0° C. to 30° C. By adjusting the glass transition temperature to a level within the preferable range, a tack property can be reduced and generation of voids between the semiconductor wafer and the die attach film, and the like can be suppressed.

Examples of the (meth)acrylic resin include a copolymer containing a (meth)acrylic acid ester component as a constituent component of the polymer. Examples of the (meth)acrylic resin constituent component include components derived from 2-hydroxyethyl acrylate, 2-hydroxyethyl methacrylate, 2-hydroxypropyl acrylate, 2-hydroxypropyl methacrylate, acrylic acid, methacrylic acid, itaconic acid, glycidylmethacrylate, glycidylacrylate, or the like. In addition, the (meth)acrylic resin may have a (meth)acrylic acid ester (e.g., (meth)acrylic acid cycloalkyl ester, (meth)acrylic acid benzyl ester, isobornyl(meth) acrylate, dicyclopentanyl (meth)acrylate, dicyclopentenyl (meth)acrylate, and dicyclopentenyloxyethyl (meth) acrylate) component having a cyclic skeleton as a constituent component. It is also possible to have an imide (meth)acrylate component or a C₁₋₁₈ (meth)acrylic acid alkyl ester (e.g., methyl (meth)acrylate, ethyl (meth)acrylate, propyl (meth)acrylate, butyl (meth)acrylate) component. Also, a copolymer containing vinyl acetate, (meth)acrylonitrile, styrene, or the like may be allowed. Further, a (meth)acrylic resin having a hydroxy group is preferable because compatibility with the epoxy resin is favorable.

The content of the polymer component (C) per 100 parts by mass of the epoxy resin (A) in the die attach film is preferably 1 to 40 parts by mass, more preferably 5 to 35 parts by mass, and further preferably 7 to 30 parts by mass. When the content is in such a range, the rigidity and flexibility of the die attach film before thermal curing are balanced, the film state is good (film tack property is reduced), and film fragility can also be suppressed.

### <Inorganic Filler (D)>

As the inorganic filler (D), an inorganic filler that can be usually used for a die attach film can be used without particular limitation.

Examples of the inorganic filler (D) include each inorganic powder made of ceramics, such as silica, clay, gypsum, calcium carbonate, barium sulfate, alumina (aluminum oxide), beryllium oxide, magnesium oxide, silicon carbide, silicon nitride, aluminum nitride, boron nitride; a metal or alloys, such as aluminum, copper, silver, gold, nickel, chromium, lead, tin, zinc, palladium, solder; and carbons, such as carbon nanotube, graphene.

The average particle diameter (d50) of the inorganic filler (D) is not particularly limited, and is preferably from 0.01 to 6.0 μm, preferably from 0.01 to 5.0 μm, and more preferably from 0.1 to 3.5 μm from the viewpoint of enhancing the die attach performance while suppressing the formation of any jig mark. The average particle diameter (d50) is a so-called median diameter, and refers to a particle diameter at which the cumulative volume is 50% when the particle size distribution is measured by the laser diffraction scattering method and the total volume of the particles is defined as 100% in the cumulative distribution. In one embodiment of the die attach film, an inorganic filler having an average particle diameter (d50) of 0.1 to 3.5 μm is included when attention is paid to the inorganic filler (D). In another preferable embodiment, it is possible to include an inorganic filler having an average particle diameter (d50) of more than 3.5 μm.

The Mohs hardness of the inorganic filler is not particularly limited, and is preferably 2 or more and more preferably from 2 to 9 from the viewpoint of enhancing the die attach performance while suppressing the occurrence of any jig mark. The Mohs hardness can be measured with a Mohs hardness meter.

The inorganic filler (D) may contain a thermally conductive inorganic filler (inorganic filler having a thermal conductivity of 12 W/m·K or more) in an embodiment, or may contain a thermally non-conductive inorganic filler (inorganic filler having a thermal conductivity of less than 12 W/m·K) in an embodiment.

The inorganic filler (D) having thermal conductivity is a particle made of a thermally conductive material or a particle whose surface is coated with the thermally conductive material. The thermal conductivity of the thermally conductive material is preferably 12 W/m·K or more, and more preferably 30 W/m·K or more.

When the thermal conductivity of the thermally conductive material is the preferable lower limit or more, the amount of the inorganic filler (D) blended in order to obtain a desired thermal conductivity can be reduced. This suppresses increase in the melt viscosity of the die attach film and enables to further improve the filling property of the film into the unevenness of the substrate at the time of compression bonding to the substrate. As a result, generation of voids can be more reliably suppressed.

In the present invention, the thermal conductivity of the thermally conductive material means the thermal conductivity at 25° C., and the literature value for each material can be used. In a case where there is no description in the literatures, for example, the value measured in accordance with JIS R 1611 can be used in the case of ceramics, or the value measured in accordance with JIS H 7801 can be used in the case of metals in substitution for the literature value.

Examples of the inorganic filler (D) having thermal conductivity include thermally conductive ceramics, and preferred examples thereof include alumina particles (thermal conductivity: 36 W/m·K), aluminum nitride particles (thermal conductivity: 150 to 290 W/m·K), boron nitride particles (thermal conductivity: 60 W/m·K), zinc oxide particles (thermal conductivity: 54 W/m·K), a silicon nitride filler (thermal conductivity: 27 W/m·K), silicon carbide particles (thermal conductivity: 200 W/m·K), and magnesium oxide particles (thermal conductivity: 59 W/m·K).

In particular, alumina particles having high thermal conductivity are preferable in terms of dispersibility and availability. Further, aluminum nitride particles and boron nitride particles are preferable from the viewpoint of having even higher thermal conductivity than that of alumina particles. In the present invention, alumina particles or aluminum nitride particles are more preferable among these particles.

Additional examples include metal particles having higher thermal conductivity than ceramic, or particles surface-coated with metal. Preferred examples include a single metal filler such as silver (thermal conductivity: 429 W/m·K), nickel (thermal conductivity: 91 W/m·K), gold (thermal conductivity: 329 W/m·K), or polymer particles such as silicone resin particles or acrylic resin particles whose surfaces are coated with these (above described) metals.

In the present invention, gold or silver particles are more preferable from the viewpoint of, in particular, high thermal conductivity and oxidation resistance deterioration.

The inorganic filler (D) may be subjected to surface treatment or surface modification. Examples of such surface treatment and surface modification include treatment with a silane coupling agent, phosphoric acid or a phosphoric acid compound, or a surfactant. Besides the items described in the present specification, the descriptions of a silane coupling agent, or phosphoric acid or a phosphoric acid compound, and a surfactant in the section of a thermally conductive filler in WO 2018/203527 or the section of an aluminum nitride filler in WO 2017/158994 can be applied, for example.

A method of blending the inorganic filler (D) to the resin components such as the epoxy resin (A), the epoxy resin curing agent (B) and the polymer component (C) includes a method in which a powder inorganic filler and, if necessary, a silane coupling agent, phosphoric acid or a phosphoric acid compound, and a surfactant are directly blended (integral blending method), and a method in which a slurry inorganic filler obtained by dispersing an inorganic filler treated with a surface treatment agent such as a silane coupling agent, phosphoric acid or a phosphoric acid compound, and a surfactant in an organic solvent is blended.

A method of treating the inorganic filler (D) with a silane coupling agent is not particularly limited. Examples thereof include a wet method for mixing the inorganic filler (D) and a silane coupling agent in a solvent, a dry method for mixing the inorganic filler (D) and a silane coupling agent in a gas phase, and the above integral blending method.

In particular, the aluminum nitride particles contribute to high thermal conductivity, but tend to generate ammonium ions due to hydrolysis. It is therefore preferable that the aluminum nitride particles are used in combination with a phenol resin having a low moisture absorption rate and hydrolysis is suppressed by surface modification. As a surface modification method of the aluminum nitride, a method for providing a surface layer with an oxide layer of aluminum oxide to improve water proofness and then preforming surface treatment with phosphoric acid or a phosphoric acid compound to improve affinity with the resin is particularly preferable.

The silane coupling agent is a compound in which at least one hydrolyzable group such as an alkoxy group or an aryloxy group is bonded to a silicon atom. In addition to these groups, an alkyl group, an alkenyl group, or an aryl group may be bonded to the silicon atom. The alkyl group is preferably an alkyl group substituted with an amino group, an alkoxy group, an epoxy group, or a (meth)acryloyloxy group, and more preferably an alkyl group substituted with an amino group (preferably, a phenylamino group), an alkoxy group (preferably, a glycidyloxy group), or a (meth)acryloyloxy group.

Examples of the silane coupling agent include 2-(3,4-epoxycyclohexyl)ethyltrimethoxysilane, 3-glycidyloxypropyltrimethoxysilane, 3-glycidyloxypropyltriethoxysilane, 3-glycidyloxypropylmethyldimethoxysilane, 3-glycidyloxypropylmethyldiethoxysilane, dimethyldimethoxysilane, dimethyldiethoxysilane, methyltrimethoxysilane, methyltriethoxysilane, phenyltrimethoxysilane, phenyltriethoxysilane, N-phenyl-3-aminopropyltrimethoxysilane, 3-methacryloyloxypropylmethyldimethoxysilane, 3-methacryloyloxypropyltrimethoxysilane, 3-methacryloyloxypropylmethyldiethoxysilane, and 3-methacryloyloxypropyltriethoxysilane.

The silane coupling agent and the surfactant are contained in an amount of preferably 0.1 to 25.0 parts by mass, more preferably 0.1 to 10 parts by mass, and further preferably 0.1 to 2.0 parts by mass based on 100 parts by mass of the inorganic filler (D).

By adjusting the content of the silane coupling agent or the surfactant to the preferable range, it is possible to suppress peeling at the adhesion interface due to volatilization of an excessive silane coupling agent and surfactant in the heating process in semiconductor assembling (for example, a reflow process) while aggregation of the inorganic filler (D) is suppressed. As a result, generation of voids can be suppressed and die attach performance can be improved.

Examples of the shape of the inorganic filler (D) include a flake shape, a needle shape, a filament shape, a spherical shape, and a scale shape. Here, a spherical particle is preferable from the viewpoint of achieving higher filling and fluidity.

In the die attach film, the proportion of the inorganic filler (D) in the total content of the epoxy resin (A), the epoxy resin curing agent (B), the polymer component (C), and the inorganic filler (D) is preferably from 5 to 70 vol %. When the content ratio of the inorganic filler (D) is equal to or more than the above lower limit, it is possible to improve the die attach performance while suppressing the occurrence of any jig mark in the die attach film. Further, a desired melt viscosity may be imparted. Also, in the case of the upper limit or less, the die attach film can be given a desired melt viscosity, and generation of voids can thus be suppressed. Further, such a content proportion allows relaxing of internal stress generated in the semiconductor package during thermal change, and also allows improvement of an adhesive force.

The proportion of the inorganic filler (D) in the total content of the epoxy resin (A), the epoxy resin curing agent (B), the polymer component (C), and the inorganic filler (D) is preferably from 10 to 70 vol %, more preferably from 20 to 60 vol %, and further preferably from 20 to 55 vol %.

The content (vol %) of the inorganic filler (D) can be calculated from the mass content and the specific gravity of each of the epoxy resin (A), the epoxy resin curing agent (B), the polymer component (C), or the inorganic filler (D).

In a preferred embodiment of the die attach film, the inorganic filler (D) has an average particle diameter (d50) of 0.01 to 5.0 μm, and the proportion of the inorganic filler (D) in the total content of the epoxy resin (A), the epoxy resin curing agent (B), the polymer component (C), and the inorganic filler (D) is from 5 to 70 vol %.

### <Other Components>

The above die attach film may further contain, for example, an organic solvent (e.g., methyl ethyl ketone), an ion trapping agent (ion capturing agent), a curing catalyst, a viscosity adjusting agent, an antioxidant, a flame retardant, and/or a coloring agent. For example, other additives described in WO 2017/158994 may be included.

The percentage of the total content of the epoxy resin (A), the epoxy resin curing agent (B), the phenoxy resin (C), and the inorganic filler (D) in the die attach film can be, for example, 60 mass % or more, preferably 70 mass % or more, further preferably 80 mass % or more, and may also be 90 mass % or more. Also, the percentage may be 100 mass %, and can be 95 mass % or less.

Subsequently, preferable characteristics of the die attach film included in the dicing die attach film of the present invention will be described.

### <Characteristics of Die Attach Film>

—Thermal Conductivity after Thermal Curing—

The thermal conductivity of the die attach film used in the present invention after thermal curing is preferably 0.8 W/m·K or more, more preferably 1.0 W/m·K or more, and still more preferably 1.4 W/m·K or more. Since the die attach film exhibits the above-described thermal conductivity after thermal curing, a semiconductor package having excellent efficiency of heat dissipation to the outside of the semiconductor package can be obtained.

The upper limit of the thermal conductivity is not particularly limited, but is usually 30 W/m·K or less.

Here, the wording “after thermal curing in the measurement of thermal conductivity” refers to a state in which curing of the die attach film has been completed. Specifically, it is a state in which no heat reaction peak is observed when DSC (Differential Scanning Calorimeter) measurement is performed at a temperature elevation rate of 10° C./min.

In the present invention, such a thermal conductivity of the die attach film after thermal curing refers to a value obtained by measuring the thermal conductivity by using a thermal conductivity measurement apparatus (trade name: HC-110, manufacture by Eko Instruments Co., Ltd) according to the heat flow meter method (in accordance with JIS-A1412). Specifically, the measurement method described in examples can be used as a reference.

In order to set the thermal conductivity within the above range, for example, the thermal conductivity can be controlled by adjusting the type and content of the inorganic filler (D).

### —Melt Viscosity—

In the die attach film, the melt viscosity at 120° C. when the die attach film before thermal curing is heated at a temperature elevation rate of 5° C./min from 25° C. is preferably in a range of 500 to 10,000 Pa·s, more preferably in a range of 1,000 to 10,000 Pa·s, and still more preferably in a range of 1,500 to 9,200 Pa·s, from the viewpoint of increasing die attach performance.

The melt viscosity can be determined by the method described in Examples described later.

Next, a method of forming a die attach film will be described.

### <Formation of Die Attach Film>

The die attach film can be formed by preparing a composition (varnish) for forming a die attach film containing constituent components of the die attach film, applying the composition onto, for example, a release-treated release film, and drying the composition. The composition for forming a die attach film usually contains a solvent.

The thickness of the die attach film is preferably 200 μm or less, more preferably 100 μm or less, even more preferably 50 μm or less, also preferably 30 μm or less, and also preferably 20 μm or less. The thickness of the die attach film is usually 1 μm or more, also preferably 2 μm or more, and may be 4 μm or more.

The thickness of the die attach film can be measured by a contact type linear gauge method (with a desk-top contact type thickness-meter).

As the release-treated release film, any release film that functions as a cover film for the die attach film to be obtained can be used, and a publicly known release film can be appropriately employed. Examples thereof include release-treated polypropylene (PP), release-treated polyethylene (PE), and release-treated polyethylene terephthalate (PET). A publicly known method can be employed, if appropriate, as the application method, and examples thereof include a method using, for instance, a roll knife coater, a gravure coater, a die coater, or a reverse coater.

The drying may be performed by removing the organic solvent from the bonding agent-use composition without curing the epoxy resin (A) to form a die attach film, and can be performed, for example, by holding the composition at a temperature of 80 to 150° C. for 1 to 20 minutes.

In the formation of the die attach film, the arithmetic average roughness Ra (Ra1) of the surface in contact with the dicing film is set to 0.05 to 2.50 μm as described above. The method of controlling Ra1 is not particularly limited, and for example, Ra1 can be controlled within a desired range by leveling the surface of the die attach film using a pressure roll. As the pressure roll, a pressure roll giving controlled surface roughness may be used.

Meanwhile, during formation of the die attach film, Ra2 is controlled such that a value of ratio (Ra1/Ra2) of Ra1 to the arithmetic average roughness Ra (Ra2) at a surface that is opposite to the surface in contact with the dicing film is from 1.05 to 28.00. Regarding Ra2, Ra2 can also be controlled within a desired range by leveling the surface of the die attach film using a pressure roll, as necessary. As the pressure roll, a pressure roll giving controlled surface roughness may be used.

Preferred ranges of Ra1, Ra2, and Ra1/Ra2 are as described above.

### <Dicing Film>

A general configuration used as a dicing film (dicing tape) can be applied, if appropriate, to the dicing film included as a component in the dicing die attach film of the present invention. In addition, as a method of forming a dicing film, a common method can be applied, if appropriate. As the temporary-adhesive constituting the dicing film, general temporary-adhesives used for application to the dicing film, for example, an acrylic temporary-adhesive, a rubber temporary-adhesive, or the like can be suitably used. Among them, the dicing film is preferably energy ray-curable.

Examples of the acrylic temporary-adhesive include a resin composed of a copolymer of (meth)acrylic acid and (meth)acrylic acid ester. As the acrylic temporary-adhesive, a resin composed of a copolymer containing (meth)acrylic acid, (meth)acrylic acid ester, and an unsaturated monomer copolymerizable with these substances (e.g., vinyl acetate, styrene, acrylonitrile) is preferably used. Further, two or more types of these resins may be mixed. Among them, preferred is a copolymer containing one or more types selected from methyl (meth)acrylate, ethylhexyl (meth)acrylate, and butyl (meth)acrylate and one or more types selected from hydroxyethyl (meth)acrylate and vinyl acetate. This facilitates control of adhesion or adhesiveness to the adherend.

In order to make the dicing film used in the present invention energy ray-curable, it is possible to introduce a polymerizable group (e.g., a carbon-carbon unsaturated bond) into a polymer constituting the dicing film or blend a polymerizable monomer in the dicing film. This polymerizable monomer preferably has two or more (preferably three or more) polymerizable groups.

Examples of the energy ray include an ultraviolet ray, an electron beam, or the like.

Regarding the configuration of the dicing film used in the present invention, for example, the descriptions of JP-A-2010-232422, Japanese Patent No. 2661950, JP-A-2002-226796, JP-A-2005-303275, and the like can be used as a reference.

The thickness of the dicing film is preferably 1 to 200 μm, more preferably 2 to 100 μm, further preferably 3 to 50 μm, and also preferably 5 to 30 μm.

In the dicing die attach film of the present invention, the peeling strength between the dicing film and the die attach film in the range of 25 to 80° C. is preferably 0.40 N/25 mm or less. This peeling strength is a peeling strength between the dicing film and the die attach film after irradiation with energy rays when the dicing film is energy ray-curable.

The peeling strength is determined according to the following conditions. Measurement condition: in accordance with JIS Z0237, 180° peel test Measurement apparatus: tensile tester (manufactured by Shimadzu Corporation, model No.: TCR1L type)

### <Production of Dicing Die Attach Film>

The method of producing a dicing die attach film according to the present invention is not particularly limited as long as the dicing film and the die attach film can be stacked to give a structure.

For example, a coating liquid containing a temporary-adhesive is applied onto a release-treated release liner and dried to form a dicing film, and then the dicing film and a substrate film are bonded. Thus, a laminated body in which the substrate film, the dicing film, and the release liner are layered in this order is produced. Separately from this, the composition for forming a die attach film is applied onto a release film (having the same meaning as a release liner, but for convenience the expression is changed here), and dried to form a die attach film on the release film. Then, the dicing film and the die attach film are bonded in such a manner that the dicing film exposed by peeling off the release liner and the die attach film are in contact. Thus, a dicing die attach film in which the substrate film, the dicing film, the die attach film, and the release film are laminated in this order can be obtained.

Bonding of the dicing film and the die attach film is preferably performed under a pressurized condition.

In the bonding of the dicing film and the die attach film, the shape of the dicing film is not particularly limited as long as the opening of a ring frame can be covered, but is preferably a circular shape. The shape of the die attach film is not particularly limited as long as the back surface of the wafer can be covered, but is preferably a circular shape. The dicing film is larger than the die attach film, and preferably has a shape having a portion where the dicing film (temporary-adhesive layer) is exposed around the die attach film (bonding agent layer) when the dicing film is bonded to the die attach film and viewed from the die attach film side. As such, it is preferable to bond the dicing film and the die attach film which are cut into a desired shape.

The dicing die attach film produced as described above is used by peeling the release film off upon use.

### [Semiconductor Package and Method of Producing the Same]

Then, preferred embodiments of a semiconductor package and a method of producing the same of the present invention will be described in detail with reference to the drawings. Note that, in the descriptions and drawings below, the same reference numerals are given to the same or corresponding components, and overlapping descriptions will be omitted. FIGS. 1 to 7 are schematic longitudinal cross-sectional views each illustrating a preferred embodiment of each step of a method of producing a semiconductor package of the present invention.

In the method of producing a semiconductor package of the present invention, as a first step, as illustrated in FIG. 1, firstly, the die attach film 2 side of the dicing die attach film of the present invention is thermocompression bonded to the back surface of a semiconductor wafer 1 where at least one semiconductor circuit is formed on the surface (that is, a surface of the semiconductor wafer 1 on which the semiconductor circuit is not formed) to provide the die attach film 2 and a dicing film 3 on the semiconductor wafer 1. In FIG. 1, the die attach film 2 is illustrated smaller than the dicing film 3, but the sizes (areas) of both films are set, if appropriate, according to the purpose. Regarding the condition of thermocompression bonding, thermocompression bonding is performed at a temperature at which the epoxy resin (A) is not thermally cured actually. Examples include the condition at a temperature of about 70° C. and a pressure of about 0.3 MPa.

As the semiconductor wafer 1, a semiconductor wafer where at least one semiconductor circuit is formed on the surface can be appropriately used. Examples thereof include a silicon wafer, a SiC wafer, a GaAs wafer, and a GaN wafer. In order to provide the dicing die attach film of the present invention on the back surface of the semiconductor wafer 1, for example, a publicly known apparatus such as a roll laminator or a manual laminator can be appropriately used.

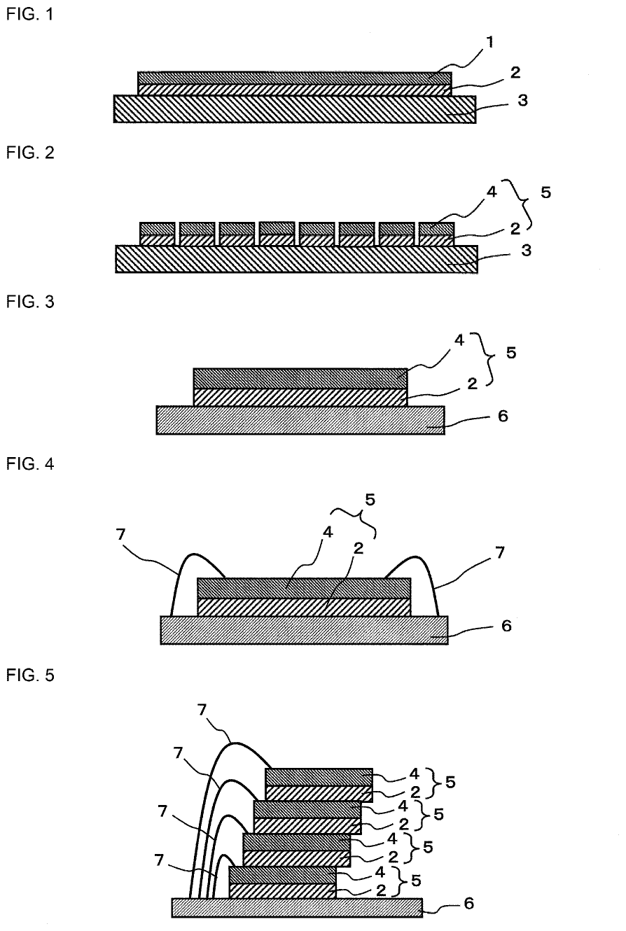

Next, as a second step, as illustrated in FIG. 2, the semiconductor wafer 1 and the die attach film 2 are integrally diced to give a semiconductor chip 5 with a bonding agent layer on the dicing film 3, the semiconductor chip 5 including a semiconductor chip 4 obtained by dicing the semiconductor wafer and a die attach film piece 2 (bonding agent layer 2) obtained by dicing the die attach film 2. Further, an apparatus used for dicing is not particularly limited, and a common dicing apparatus can be used, if appropriate.

Next, as a third step, the dicing film is cured with energy rays as necessary to reduce the adhesive force, and the bonding agent layer 2 is peeled off from the dicing film 3 by pickup. Then, as illustrated in FIG. 3, the semiconductor chip 5 with a bonding agent layer and the circuit board 6 are thermocompression bonded via the bonding agent layer 2 to mount the semiconductor chip 5 with a bonding agent layer on the circuit board 6. As the circuit board 6, a substrate where a semiconductor circuit is formed on the surface can be appropriately used. Examples thereof include a print circuit board (PCB), various lead frames, and a substrate where electronic components such as a resistive element and a capacitor are mounted on the surface of a substrate.

A method of mounting the semiconductor chip 5 with a bonding agent layer on such a circuit board 6 is not particularly limited, and a conventional thermocompression bonding-mediated mounting method can be adopted, if appropriate.

Then, as a fourth step, the bonding agent layer 2 is thermally cured. The temperature of the thermal curing is not particularly limited as long as the temperature is equal to or higher than a temperature at which thermal curing starts in the bonding agent layer 2, and is adjusted, if appropriate, depending on the types of the epoxy resin (A), the polymer component (C), and the epoxy curing agent (B) used. For example, the temperature is preferably from 100 to 180° C. and more preferably from 140 to 180° C. from the viewpoint of curing in a shorter time. If the temperature is too high, the components in the bonding agent layer 2 tend to be volatilized during the curing process. This is likely to cause foaming. The duration of this thermal curing treatment may be set, if appropriate, according to the heating temperature, and can be, for example, from 10 to 120 minutes.

In the method of producing a semiconductor package of the present invention, it is preferable that the circuit board 6 and the semiconductor chip 5 with a bonding agent layer are connected via a bonding wire 7 as illustrated in FIG. 4. Such a connection method is not particularly limited, and a publicly known method, for example, a wire bonding method or a TAB (Tape Automated Bonding) method can be employed, if appropriate.

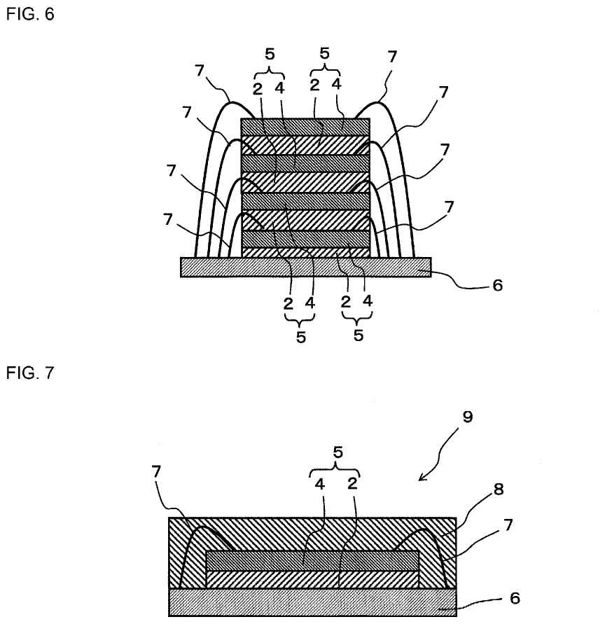

Further, a plurality of semiconductor chips 4 can be stacked by thermocompression bonding another semiconductor chip 4 to a surface of the mounted semiconductor chip 4, performing thermal curing, and then connecting the semiconductor chips 4 again to the circuit board 6 by wire bonding. Examples of the stacking method include a method of stacking the semiconductor chips in slightly different positions as illustrated in FIG. 5, and a method of stacking the semiconductor chips by increasing the thicknesses of the bonding agent layers 2 of the second layer or later and thereby embedding the bonding wire 7 in each bonding agent layer 2 as illustrated in FIG. 6.

In the method of producing a semiconductor package of the present invention, it is preferable to seal the circuit board 6 and the semiconductor chip 5 with a bonding agent layer by using a sealing resin 8 as illustrated in FIG. 7. In this way, a semiconductor package 9 can be obtained. The sealing resin 8 is not particularly limited, and a publicly known sealing resin that can be used for the production of the semiconductor package can be used, if appropriate. In addition, a sealing method using the sealing resin 8 is not particularly limited, and a routinely conducted method can be employed.

### EXAMPLES

Hereinafter, the present invention will be described in more detail based on Examples and Comparative Examples. However, the present invention is not limited to the following Examples. Meanwhile, the room temperature means 25° C., and MEK means methyl ethyl ketone.

### Example 1

### <Production of Dicing Film (Temporary-Adhesive Layer)]

### (1) Production of Substrate Film

Resin pellets of low density polyethylene (LDPE, density: 0.92 g/cm³, melting point: 110° C.) were melted at 230° C. and then extruded into a long film with a thickness of 70 μm by using an extruder. The obtained film was irradiated with 100 kGy of electron beams, thus producing a substrate film.

### (2) Formation of Dicing Film

A copolymer containing 50 mol % of butylacrylate, 45 mol % of 2-hydroxyethyl acrylate, and 5 mol % of methacrylic acid and having a mass average molecular weight of 800,000 was prepared. Next, 2-isocyanatoethyl methacrylate was added to the copolymer so that the iodine value was 20, thus preparing an acrylic copolymer having a glass transition temperature of −40° C., a hydroxyl value of 30 mgKOH/g, and an acid value of 5 mgKOH/g.

Thereafter, 5 parts by mass of Coronate L (trade name, manufactured by Nippon Polyurethane Industry Co., Ltd.) as polyisocyanate and 3 parts by mass of Esacure KIP 150 (trade name, manufactured by Lamberti) as a photopolymerization initiator were added to 100 parts by mass of the prepared acrylic copolymer to prepare a mixture. The mixture was dissolved in ethyl acetate and the solution was stirred to prepare a temporary-adhesive composition.

Then, this temporary-adhesive composition was applied onto a release liner made of a release-treated polyethylene terephthalate (PET) film to have a dry thickness of 20 μm, and then dried at 110° C. for 3 minutes, thus forming a dicing film. The prepared substrate film and the dicing film were bonded to produce a laminate in which three layers of the release liner, the dicing film, and the substrate film are stacked.

### <Production of Die Attach Film (Bonding Agent Layer)>

In a 1,000-mL separable flask, 56 parts by mass of triphenylmethane type epoxy resin (trade name: EPPN-501H, mass average molecular weight: 1,000, softening point: 55° C., semi-solid, epoxy equivalent amount: 167 g/eq, manufactured by Nippon Kayaku Co., Ltd.), 49 parts by mass of bisphenol A type epoxy resin (trade name: YD-128, mass average molecular weight: 400, softening point: less than 25° C., liquid, epoxy equivalent amount: 190 g/eq, manufactured by NSCC Epoxy Manufacturing Co., Ltd.), 10 parts by mass of bisphenol A type phenoxy resin (trade name: YP-50, mass average molecular weight: 70,000, Tg: 84° C., normal temperature (25° C.) elastic modulus: 1,700 MPa, manufactured by NSCC Epoxy Manufacturing Co., Ltd.), and 67 parts by mass of MEK were heated with stirring at 110° C. for 2 hours, thus obtaining a resin varnish.

Subsequently, this resin varnish was transferred to an 800-mL planetary mixer, and 205 parts by mass of alumina filler (trade name: AO-502, manufactured by Admatechs, average particle diameter (d50): 0.6 μm) was introduced to the mixer. Further, 8.5 parts by mass of imidazole-based curing agent (trade name: 2PHZ-PW, manufactured by Shikoku Chemicals Corporation) and 3.0 parts by mass of silane coupling agent (trade name: Sila-Ace S-510, manufactured by JNC Corporation) were introduced to the mixer, and the contents were then mixed with stirring for 1 hour at room temperature. Then defoaming under vacuum was conducted, thus obtaining a mixed varnish (composition for forming a die attach film).

Thereafter, the resulting mixed varnish was applied onto the release-treated surface of a release-treated PET film (release film) having a thickness of 38 μm and dried by heating at 130° C. for 10 minutes. Thus, a 2-layer laminated body in which a die attach film having a length of 300 mm, a width of 200 mm, and a thickness of 10 μm was formed on the release film was produced.

Next, the surface of the die attach film on the side opposite to the release film side was leveled with a pressure roll (model number: UNA-980BK; surface roughness Ra: 5-8 μm; trade name: TOSICAL Roll; manufactured by Tosico Corporation) under conditions at a load of 0.4 MPa and a speed of 1.0 m/min, and the arithmetic average roughness Ra (Ra1) of the die attach film surface was controlled as follows.

### <Production of Dicing Die Attach Film>

Then, the dicing film-containing 3-layer laminated body was cut into a circular shape so that the laminated body can be bonded to cover the opening of a ring frame. Further, the die attach film-containing 2-layer laminated body was cut into a circular shape to cover the back surface of the wafer.

The dicing film exposed by peeling off the release liner from the 3-layer laminated body cut as described above and the die attach film of the 2-layer laminated body cut as described above were bonded by using a roll press machine under conditions at a load of 0.4 MPa and a rate of 1.0 m/min, thus producing a dicing die attach film, in which the substrate film, the dicing film, the die attach film, and the release film were layered in this order. The dicing film was larger than the die attach film in this dicing die attach film, and this dicing die attach film had a portion where the dicing film was exposed around the die attach film.

### Example 2

A dicing die attach film was produced in the same manner as in Example 1 except that the pressure roll used to control the surface roughness of the die attach film in Example 1 was replaced by a pressure roll (model number: UNA-800GY; surface roughness Ra: 8-12 μm; trade name: TOSICAL ROLL; manufactured by Tosico Corporation).

### Example 3

A dicing die attach film was produced in the same manner as in Example 1 except that the pressure roll used to control the surface roughness of the die attach film in Example 1 was replaced by a pressure roll (model number: UNA-900BK; surface roughness Ra: 10-15 μm; trade name: TOSICAL ROLL; manufactured by Tosico Corporation).

### Example 4

A dicing die attach film was produced in the same manner as in Example 1 except that the pressure roll used to control the surface roughness of the die attach film in Example 1 was replaced by a pressure roll (model number: UNA-340-X10; surface roughness Ra: 35-45 μm; trade name; TOSICAL ROLL; manufactured by Tosico Corporation).

### Example 5

The same procedure as in Example 1 was repeated, except that the amount of alumina filler used as a component of the die attach film in Example 1 was changed to 479 parts by mass, to produce a dicing die attach film.

### Example 6

A dicing die attach film was produced in the same manner as in Example 5 except that the pressure roll used to control the surface roughness of the die attach film in Example 5 was replaced by a pressure roll (model number: UNA-800GY; surface roughness Ra: 8-12 μm; trade name: TOSICAL ROLL; manufactured by Tosico Corporation).

### Example 7

A dicing die attach film was produced in the same manner as in Example 5 except that the pressure roll used to control the surface roughness of the die attach film in Example 5 was replaced by a pressure roll (model number: UNA-900BK; surface roughness Ra: 10-15 μm; trade name: TOSICAL ROLL; manufactured by Tosico Corporation).

### Example 8

A dicing die attach film was produced in the same manner as in Example 5 except that the pressure roll used to control the surface roughness of the die attach film in Example 5 was replaced by a pressure roll (model number: UNA-340-X10; surface roughness Ra: 35-45 μm; trade name; TOSICAL ROLL; manufactured by Tosico Corporation).

### Example 9

The same procedure as in Example 1 was repeated, except that 360 parts by mass of silver filler (trade name: AG-4-8F; manufactured by DOWA Electronics Materials Co., Ltd.; with an average particle diameter (d50): 2.0 μm) was used instead of alumina filler as a component of the die attach film in Example 1, to produce a dicing die attach film.

### Example 10

A dicing die attach film was produced in the same manner as in Example 9 except that the pressure roll used to control the surface roughness of the die attach film in Example 9 was replaced by a pressure roll (model number: UNA-800GY; surface roughness Ra: 8-12 μm; trade name: TOSICAL ROLL; manufactured by Tosico Corporation).

### Example 11

A dicing die attach film was produced in the same manner as in Example 9 except that the pressure roll used to control the surface roughness of the die attach film in Example 9 was replaced by a pressure roll (model number: UNA-900BK; surface roughness Ra: 10-15 μm; trade name: TOSICAL ROLL; manufactured by Tosico Corporation).

### Example 12

A dicing die attach film was produced in the same manner as in Example 9 except that the pressure roll used to control the surface roughness of the die attach film in Example 9 was replaced by a pressure roll (model number: UNA-340-X10; surface roughness Ra: 35-45 μm; trade name; TOSICAL ROLL; manufactured by Tosico Corporation).

### Example 13

The same procedure as in Example 1 was repeated, except that 950 parts by mass of silver filler (trade name: AG-4-8F; manufactured by DOWA Electronics Materials Co., Ltd.; with an average particle diameter (d50): 2.0 μm) was used instead of alumina filler as a component of the die attach film in Example 1, to produce a dicing die attach film.

### Example 14

A dicing die attach film was produced in the same manner as in Example 13 except that the pressure roll used to control the surface roughness of the die attach film in Example 13 was replaced by a pressure roll (model number: UNA-800GY; surface roughness Ra: 8-12 μm; trade name: TOSICAL ROLL; manufactured by Tosico Corporation).

### Example 15

A dicing die attach film was produced in the same manner as in Example 13 except that the pressure roll used to control the surface roughness of the die attach film in Example 13 was replaced by a pressure roll (model number: UNA-900BK; surface roughness Ra: 10-15 μm; trade name: TOSICAL ROLL; manufactured by Tosico Corporation).

### Example 16

A dicing die attach film was produced in the same manner as in Example 13 except that the pressure roll used to control the surface roughness of the die attach film in Example 13 was replaced by a pressure roll (model number: UNA-340-X10; surface roughness Ra: 35-45 μm; trade name; TOSICAL ROLL; manufactured by Tosico Corporation).

### Example 17

The same procedure as in Example 2 was repeated, except that instead of bisphenol A-type phenoxy resin, which was a component of the die attach film, 120 parts by mass (including 30 parts by mass of acrylic polymer) of acrylic resin solution (trade name: S-2060; mass average molecular weight: 500,000; Tg: −23° C.; room temperature (25° C.) elastic modulus: 50 MPa; solid content: 25% (organic solvent: toluene); manufactured by TOAGOSEI CO., LTD.) was used and the amount of alumina filler used was changed to 320 parts by mass in Example 2, to produce a dicing die attach film.

### Comparative Example 1

A dicing die attach film was produced in the same manner as in Example 1 except that the pressure roll used to control the surface roughness of the die attach film in Example 1 was replaced by a pressure roll (model number: UNA-102CR; surface roughness Ra: 0.5-1.5 μm; trade name; TOSICAL ROLL; manufactured by Tosico Corporation).

### Comparative Example 2

The same procedure as in Comparative Example 1 was repeated, except that the amount of alumina filler used as a component of the die attach film in Comparative Example 1 was changed to 479 parts by mass, to produce a dicing die attach film.

### Comparative Example 3

The same procedure as in Comparative Example 1 was repeated, except that 360 parts by mass of silver filler (trade name: AG-4-8F; manufactured by DOWA Electronics Materials Co., Ltd.; with an average particle diameter (d50): 2.0 μm) was used instead of alumina filler as a component of the die attach film in Comparative Example 1, to produce a dicing die attach film.

### Comparative Example 4

The same procedure as in Comparative Example 3 was repeated, except that the amount of silver filler used as a component of the die attach film in Comparative Example 3 was changed to 950 parts by mass, to produce a dicing die attach film.

### Comparative Example 5

In the dicing die attach film produced in Example 7, the release film was once peeled off, the arithmetic average roughness Ra (Ra2) at the surface that was of the die attach film and in contact with the release film was controlled with a pressure roll (model number: UNA-900BK; surface roughness Ra: 10-15 μm; trade name; TOSICAL ROLL; manufactured by Tosico Corporation) as in the following table, and then the peeled release film was bonded again to prepare a dicing die attach film.

### Comparative Example 6

In the dicing die attach film produced in Example 16, the release film was once peeled off, the surface roughness Ra (Ra2) at the surface that was of the die attach film and in contact with the release film was controlled with a pressure roll (model number: UNA-340-X10; surface roughness Ra: 35-45 μm; trade name; TOSICAL ROLL; manufactured by Tosico Corporation) as in the following table, and then the peeled release film was bonded again to prepare a dicing die attach film.

### Comparative Example 7

In the dicing die attach film produced in Example 17, the release film was once peeled off, the surface roughness Ra (Ra2) at the surface that was of the die attach film and in contact with the release film was controlled with a pressure roll (model number: UNA-800GY; surface roughness Ra: 8-12 μm; trade name; TOSICAL ROLL; manufactured by Tosico Corporation) as in the following table, and then the peeled release film was bonded again to prepare a dicing die attach film.

### [Measurement/Test/Evaluation]

Each dicing die attach film obtained in each of the above Examples or Comparative Examples was measured, tested, and evaluated with respect to the following items.

The tables below collectively provide the results.

### <Arithmetic Average Roughness Ra1 of Die Attach Film>

Each dicing die attach film was irradiated with ultraviolet rays from the dicing film side while using an ultraviolet irradiation device (trade name: RAD-2000F/8, manufactured by LINTEC Corporation; irradiation amount: 200 mJ/cm²); the dicing film was then peeled off from the die attach film; and the arithmetic average roughness Ra1 at the dicing film-side surface of the die attach film was measured using a surface roughness measuring instrument (model: SJ-201, manufactured by Mitutoyo Corporation). The measurement conditions were as follows.

Cut-off value: 2.5 mm

Evaluation length: 12.4 mm

Measurement speed: 0.5 mm/s

Stylus tip radius (R): 2 μm

### <Arithmetic Average Roughness Ra2 of Die Attach Film>

Each dicing die attach film was irradiated with ultraviolet rays from the dicing film side while using an ultraviolet irradiation device (trade name: RAD-2000F/8, manufactured by LINTEC Corporation; irradiation amount: 200 mJ/cm²); the dicing film was then peeled off from the die attach film; the exposed die attach film surface was bonded to a dummy silicon wafer with a diameter of 5 inches and a thickness of 470 μm and the release film was subsequently peeled off; and the arithmetic average roughness Ra2 at the release film-side surface of the die attach film was measured using a surface roughness measuring instrument (model: SJ-201, manufactured by Mitutoyo Corporation). The measurement conditions were as follows.

Cut-off value: 2.5 mm

Evaluation length: 12.4 mm

Measurement speed: 0.5 mm/s

Stylus tip radius (R): 2 μm

### <Melt Viscosity of Die Attach Film>

Each dicing die attach film was cut out into pieces with a size of length 5.0 cm×width 5.0 cm, and each piece was irradiated with ultraviolet rays from the dicing film side while using an ultraviolet irradiation device (trade name: RAD-2000F/8, manufactured by LINTEC Corporation; irradiation amount: 200 mJ/cm²); the dicing film and the release film were then peeled off from the die attach film; and the remaining die attach film portion was used as a sample. For each dicing die attach film, a plurality of samples were prepared, laminated, and bonded on a hot plate at a stage temperature of 70° C. by using a hand roller to give a test piece of bonding agent layer having a thickness of about 1.0 mm.

A change in viscosity resistance in a temperature range of 20 to 250° C. at a temperature elevation rate of 5° C./min was measured for this test piece by using a rheometer (RS6000, manufactured by Haake). The melt viscosities at 120° C. (Pa·s) were each calculated from the obtained temperature-viscosity resistance curve.

<Thermal Conductivity of Die Attach Film after Thermal Curing>

Each dicing die attach film was cut out into square pieces with a side of 50 mm or more, and each piece was irradiated with ultraviolet rays from the dicing film side while using an ultraviolet irradiation device (trade name: RAD-2000F/8, manufactured by LINTEC Corporation; irradiation amount: 200 mJ/cm²); the dicing film and the release film were then peeled off from the die attach film; and the remaining die attach film portion was used as a sample. For each dicing die attach film, a plurality of samples were prepared and laminated to obtain a laminate having a thickness of 5 mm or more.

This laminate sample was placed on a disk-shaped mold with a diameter of 50 mm and a thickness 5 mm, heated at a temperature of 150° C. under a pressure of 2 MPa for 10 minutes by using a compression molding machine, and then taken out. The sample was further heated in a dryer at a temperature of 180° C. for 1 hour to thermally cure the bonding agent layer. Thus, a disk-shaped test piece having a diameter of 50 mm and a thickness of 5 mm was obtained.

The thermal conductivity (W/(m·K)) was measured for this test piece by using a thermal conductivity measurement apparatus (trade name: HC-110, manufacture by Eko Instruments Co., Ltd) according to the heat flow meter method (in accordance with JIS-A1412).

### <Evaluation of Continuous Pickup Property>

For each dicing die attach film, the release film was first peeled off. The die attach film surface exposed was then bonded to one surface of a dummy silicon wafer (size: 8 inch, thickness: 100 μm) by using a manual laminator (trade name: FM-114, manufactured by Technovision, Inc.) under conditions at a temperature of 70° C. and a pressure of 0.3 MPa. Then, dicing was performed from the dummy silicon wafer side to form squares each having a size of 5 mm×5 mm by using a dicing apparatus (trade name: DFD-6340, manufactured by DISCO Corporation) equipped with two axes of dicing blades (Z1: NBC-ZH2050 (27HEDD), manufactured by DISCO Corporation/Z2: NBC-ZH127F-SE(BC), manufactured by DISCO Corporation), thus obtaining each dummy chip with a diced die attach film piece (a bonding agent layer) on the dicing film.

Subsequently, the prepared dummy chip with a bonding agent layer was irradiated with ultraviolet rays from the back surface side of the wafer by using an ultraviolet irradiation device (trade name: RAD-2000F/8, manufactured by Lintec Corporation, irradiation amount: 200 mJ/cm²). Then, the dummy chip with a bonding agent layer was picked up under the following pickup conditions and pasted on and thermocompression bonded to the mounting surface side of a lead frame substrate (42Arroy-based, manufactured by Toppan Printing Co., Ltd.) by using a die bonder (trade name: DB-800, manufactured by Hitachi High-Tech Corporation) under the following die attach conditions. This step of picking up and thermocompression bonding was continuously repeated, and the continuous pickup property was evaluated based on the following criteria.

### —Pickup Conditions—

Number of needles: 5 (350R), needle height: 200 μm, pickup timer: 100 msec or 300 msec

### —Die Attach Conditions—

120° C., pressure 0.1 MPa (load 400 gf), time 1.0 second

### —Evaluation Criteria—

AA: No remaining bonding agent layer on the dicing film is observed, in visual observation, in all of 192 dummy chips which have been continuously picked up using a pickup timer at 100 msec and thermocompression bonded.
A: The results do not fall under AA, but no remaining bonding agent layer on the dicing film is observed, in visual observation, in all of 192 dummy chips which have been continuously picked up using a pickup timer at 300 msec and thermocompression bonded.
B: The results do not fall under AA, and 1 to 2 remaining bonding agent layers on the dicing film occur, in visual observation, in 192 dummy chips which have been continuously picked up using a pickup timer at 300 msec and thermocompression bonded.
C: The results do not fall under AA, and 3 to 10 remaining bonding agent layers on the dicing film occur, in visual observation, in 192 dummy chips which have been continuously picked up using a pickup timer at 300 msec and thermocompression bonded.
D: The results do not fall under AA, and 11 or more remaining bonding agent layers on the dicing film occur, in visual observation, in 192 dummy chips which have been continuously picked up using a pickup timer at 300 msec and thermocompression bonded.

TABLE 1

| | | | Example | | | |
|---|---|---|---|---|---|---|
| | | | 1 | 2 | 3 | 4 |
| Die attach | Epoxy | EPPN-501H | 56 | 56 | 56 | 56 |
| film | resin | (triphenylmethane-type epoxy | | | | |
| composition | | resin) | | | | |
| (parts | | YD-128 | 49 | 49 | 49 | 49 |
| by mass) | | (liquid Bis A-type epoxy resin) | | | | |
| | Polymer | YP-50 | 10 | 10 | 10 | 10 |
| | component | (Bis A-type phenoxy resin) | | | | |
| | | S-2060 (acrylic resin) | | | | |
| | Inorganic | AO502 (alumina) | 205 | 205 | 205 | 205 |
| | filler | AG-4-8F (silver) | | | | |

| | | | | |
|---|---|---|---|---|
| S-510 | 3.0 | 3.0 | 3.0 | 3.0 |
| (epoxysilane-type silane coupling agent) | | | | |
| 2PHZ-PW (imidazole-based curing agent) | 8.5 | 8.5 | 8.5 | 8.5 |
| Total solid content | 331 | 331 | 331 | 331 |
| Inorganic filler content (vol %) | 33% | 33% | 33% | 33% |

| Pressure roll model number (surface roughness) | UNA-980BK | UNA-800GY | UNA-900BK | UNA-340-X10 |
|---|---|---|---|---|
| | (Ra5-8 μm) | (Ra8-12 μm) | (Ra10-15 μm) | (Ra35-45 μm) |
| Arithmetic average roughness Ra1 of die | 0.14 | 0.35 | 0.60 | 2.20 |
| attach film (μm, dicing film side) | | | | |
| Arithmetic average roughness Ra2 of die | 0.13 | 0.13 | 0.13 | 0.13 |
| attach film (μm, release film side, wafer side) | | | | |
| Ra1/Ra2 | 1.08 | 2.69 | 4.62 | 16.92 |
| Melt viscosity (Pa · s) of die attach film at 120° C. | 4900 | 4900 | 4900 | 4900 |
| Thermal conductivity of die attach film | 1.0 | 1.0 | 1.0 | 1.0 |
| after thermal curing (W/m · K) | | | | |
| Evaluation of pickup property | A | A | AA | AA |

| | | | Example | | | | |
|---|---|---|---|---|---|---|---|
| | | | 5 | 6 | 7 | 8 | 9 |
| Die attach | Epoxy | EPPN-501H | 56 | 56 | 56 | 56 | 56 |
| film | resin | (triphenylmethane-type epoxy | | | | | |
| composition | | resin) | | | | | |
| (parts | | YD-128 | 49 | 49 | 49 | 49 | 49 |
| by mass) | | (liquid Bis A-type epoxy resin) | | | | | |
| | Polymer | YP-50 | 10 | 10 | 10 | 10 | 10 |
| | component | (Bis A-type phenoxy resin) | | | | | |
| | | S-2060 (acrylic resin) | | | | | |
| | Inorganic | AO502 (alumina) | 479 | 479 | 479 | 479 | |
| | filler | AG-4-8F (silver) | | | | | 360 |

| | | | | | |
|---|---|---|---|---|---|
| S-510 | 3.0 | 3.0 | 3.0 | 3.0 | 3.0 |
| (epoxysilane-type silane coupling agent) | | | | | |
| 2PHZ-PW (imidazole-based curing agent) | 8.5 | 8.5 | 8.5 | 8.5 | 8.5 |
| Total solid content | 605 | 605 | 605 | 605 | 486 |
| Inorganic filler content (vol %) | 54% | 54% | 54% | 54% | 25% |

| Pressure roll model number (surface roughness) | UNA-980BK | UNA-800GY | UNA-900BK | UNA-340-X10 | UNA-980BK |
|---|---|---|---|---|---|
| | (Ra5-8 μm) | (Ra8-12 μm) | (Ra10-15 μm) | (Ra35-45 μm) | (Ra5-8 μm) |
| Arithmetic average roughness Ra1 of die | 0.35 | 0.55 | 0.70 | 2.50 | 0.24 |
| attach film (μm, dicing film side) | | | | | |
| Arithmetic average roughness Ra2 of die | 0.14 | 0.14 | 0.14 | 0.14 | 0.08 |
| attach film (μm, release film side, wafer side) | | | | | |
| Ra1/Ra2 | 2.50 | 3.93 | 5.00 | 17.86 | 3.00 |
| Melt viscosity (Pa · s) of die attach film at 120° C. | 7500 | 7500 | 7500 | 7500 | 560 |
| Thermal conductivity of die attach film | 1.8 | 1.8 | 1.8 | 1.8 | 6.2 |
| after thermal curing (W/m · K) | | | | | |
| Evaluation of pickup property | A | A | AA | AA | A |

| | | | Example | | |
|---|---|---|---|---|---|
| | | | 10 | 11 | 12 |
| Die attach | Epoxy | EPPN-501H | 56 | 56 | 56 |
| film | resin | (triphenylmethane-type epoxy | | | |
| composition | | resin) | | | |
| (parts | | YD-128 | 49 | 49 | 49 |
| by mass) | | (liquid Bis A-type epoxy resin) | | | |
| | Polymer | YP-50 | 10 | 10 | 10 |
| | component | (Bis A-type phenoxy resin) | | | |
| | | S-2060 (acrylic resin) | | | |
| | Inorganic | AO502 (alumina) | | | |
| | filler | AG-4-8F (silver) | 360 | 360 | 360 |

| | | | |
|---|---|---|---|
| S-510 | 3.0 | 3.0 | 3.0 |
| (epoxysilane-type silane coupling agent) | | | |
| 2PHZ-PW (imidazole-based curing agent) | 8.5 | 8.5 | 8.5 |
| Total solid content | 486 | 486 | 486 |
| Inorganic filler content (vol %) | 25% | 25% | 25% |

| Pressure roll model number (surface roughness) | UNA-800GY | UNA-900BK | UNA-340-X10 |
|---|---|---|---|
| | (Ra8-12 μm) | (Ra10-15 μm) | (Ra35-45 μm) |
| Arithmetic average roughness Ra1 of die | 0.55 | 0.82 | 2.10 |
| attach film (μm, dicing film side) | | | |
| Arithmetic average roughness Ra2 of die | 0.08 | 0.08 | 0.08 |
| attach film (μm, release film side, wafer side) | | | |
| Ra1/Ra2 | 6.88 | 10.25 | 26.25 |
| Melt viscosity (Pa · s) of die attach film at 120° C. | 560 | 560 | 560 |
| Thermal conductivity of die attach film | 6.2 | 6.2 | 6.2 |
| after thermal curing (W/m · K) | | | |
| Evaluation of pickup property | A | AA | AA |

| | | | Example | | | | |
|---|---|---|---|---|---|---|---|
| | | | 13 | 14 | 15 | 16 | 17 |
| Die attach | Epoxy | EPPN-501H | 56 | 56 | 56 | 56 | 56 |
| film | resin | (triphenylmethane-type epoxy | | | | | |
| composition | | resin) | | | | | |
| (parts | | YD-128 | 49 | 49 | 49 | 49 | 49 |
| by mass) | | (liquid Bis A-type epoxy resin) | | | | | |
| | Polymer | YP-50 | 10 | 10 | 10 | 10 | |
| | component | (Bis A-type phenoxy resin) | | | | | |
| | | S-2060 (acrylic resin) | | | | | 30 |
| | Inorganic | AO502 (alumina) | | | | | 320 |
| | filler | AG-4-8F (silver) | 950 | 950 | 950 | 950 | |

| | | | | | |
|---|---|---|---|---|---|
| S-510 | 3.0 | 3.0 | 3.0 | 3.0 | 3.0 |
| (epoxysilane-type silane coupling agent) | | | | | |
| 2PHZ-PW | 8.5 | 8.5 | 8.5 | 8.5 | 8.5 |
| (imidazole-based curing agent) | | | | | |
| Total solid content | 1076 | 1076 | 1076 | 1076 | 467 |
| Inorganic filler content (vol %) | 46% | 46% | 46% | 46% | 40% |

| Pressure roll model number (surface roughness) | UNA-980BK | UNA-800GY | UNA-900BK | UNA-340-X10 | UNA-800GY |
|---|---|---|---|---|---|
| | (Ra5-8 μm) | (Ra8-12 μm) | (Ra10-15 μm) | (Ra35-45 μm) | (Ra8-12 μm) |
| Arithmetic average roughness Ra1 of die | 0.24 | 0.76 | 1.50 | 2.20 | 0.50 |
| attach film (μm, dicing film side) | | | | | |
| Arithmetic average roughness Ra2 of die | 0.09 | 0.09 | 0.09 | 0.09 | 0.12 |
| attach film (μm, release film side, wafer side) | | | | | |
| Ra1/Ra2 | 2.67 | 8.44 | 16.67 | 24.44 | 4.17 |
| Melt viscosity (Pa · s) of die attach film at 120° C. | 7760 | 7760 | 7760 | 7760 | 9000 |
| Thermal conductivity of die attach film | 26.2 | 26.2 | 26.2 | 26.2 | 1.4 |
| after thermal curing (W/m · K) | | | | | |
| Evaluation of pickup property | A | AA | AA | AA | A |

TABLE 2

| | | | Comparative Example | | | |
|---|---|---|---|---|---|---|
| | | | 1 | 2 | 3 | 4 |
| Die attach | Epoxy | EPPN-501H | 56 | 56 | 56 | 56 |
| film | resin | (triphenylmethane-type epoxy | | | | |
| composition | | resin) | | | | |
| (parts | | YD-128 | 49 | 49 | 49 | 49 |
| by mass) | | (liquid Bis A-type epoxy resin) | | | | |
| | Polymer | YP-50 | 10 | 10 | 10 | 10 |
| | component | (Bis A-type phenoxy resin) | | | | |
| | | S-2060 (acrylic resin) | | | | |
| | Inorganic | AO502 (alumina) | 205 | 479 | | |
| | filler | AG-4-8F (silver) | | | 360 | 950 |

| | | | | |
|---|---|---|---|---|
| S-510 | 3.0 | 3.0 | 3.0 | 3.0 |
| (epoxysilane-type silane coupling agent) | | | | |
| 2PHZ-PW (imidazole-based curing agent) | 8.5 | 8.5 | 8.5 | 8.5 |
| Total solid content | 331 | 605 | 486 | 1076 |
| Inorganic filler content (vol %) | 33% | 54% | 25% | 46% |

| Pressure roll model number (surface roughness) | UNA-102CR) | UNA-102CR | UNA-102CR | UNA-102CR |
|---|---|---|---|---|
| | (Ra0.5-1.5 μm | (Ra0.5-1.5 μm) | (Ra0.5-1.5 μm) | (Ra0.5-1.5 μm) |
| Arithmetic average roughness Ra1 of die | 0.13 | 0.14 | 0.08 | 0.09 |
| attach film (μm, dicing film side) | | | | |
| Arithmetic average roughness Ra2 of die | 0.13 | 0.14 | 0.08 | 0.09 |
| attach film (μm, release film side, wafer side) | | | | |
| Ra1/Ra2 | 1.00 | 1.00 | 1.00 | 1.00 |
| Melt viscosity (Pa · s) of die attach film at 120° C. | 4900 | 7500 | 560 | 7760 |
| Thermal conductivity of die attach film | 1.0 | 1.8 | 6.2 | 26.2 |
| after thermal curing (W/m · K) | | | | |
| Evaluation of pickup property | C | C | C | C |

| | | | Comparative Example | | |
|---|---|---|---|---|---|
| | | | 5 | 6 | 7 |
| Die attach | Epoxy | EPPN-501H | 56 | 56 | 56 |
| film | resin | (triphenylmethane-type epoxy | | | |
| composition | | resin) | | | |
| (parts | | YD-128 | 49 | 49 | 49 |
| by mass) | | (liquid Bis A-type epoxy resin) | | | |
| | Polymer | YP-50 | 10 | 10 | |
| | component | (Bis A-type phenoxy resin) | | | |
| | | S-2060 (acrylic resin) | | | 30 |
| | Inorganic | AO502 (alumina) | 479 | | 320 |
| | filler | AG-4-8F (silver) | | 950 | |

| | | | |
|---|---|---|---|
| S-510 | 3.0 | 3.0 | 3.0 |
| (epoxysilane-type silane coupling agent) | | | |
| 2PHZ-PW (imidazole-based curing agent) | 8.5 | 8.5 | 8.5 |
| Total solid content | 605 | 1076 | 467 |
| Inorganic filler content (vol %) | 54% | 46% | 40% |

| Pressure roll model number (surface roughness) | UNA-900BK* | UNA-340-X10* | UNA-800GY* |
|---|---|---|---|
| | (Ra10-15 μm) | (Ra35-45 μm) | (Ra8-12 μm) |
| Arithmetic average roughness Ra1 of die | 0.70 | 2.20 | 0.50 |
| attach film (μm, dicing film side) | | | |
| Arithmetic average roughness Ra2 of die | 0.72 | 2.22 | 0.52 |
| attach film (μm, release film side, wafer side) | | | |
| Ra1/Ra2 | 0.97 | 0.99 | 0.96 |
| Melt viscosity (Pa · s) of die attach | 7500 | 7760 | 9000 |
| film at 120° C. | | | |
| Thermal conductivity of die attach film | 1.8 | 26.2 | 1.4 |
| after thermal curing (W/m · K) | | | |
| Evaluation of pickup property | C | D | C |

*The bonding agent layer surface, from which the release film had been peeled off, was leveled with the same pressure roll.

As shown in Tables 1 and 2, in the dicing die attach film of any of Comparative Examples 1 to 7 in which Ra1/Ra2 was smaller than that specified in the present invention, some pickup failure was likely to occur. By contrast, it can be seen that in all of the dicing die attach films of Examples 1 to 17 in which Ra1/Ra2 satisfies the requirements of the present invention, the occurrence of pickup failure is remarkably suppressed. In addition, these results indicate that the above technical significance of setting Ra1/Ra2 to 1.05 or more is expressed regardless of the magnitude of Ra1.

In all the dicing die attach films of Examples or Comparative Examples, the peeling strength (180° peel test in accordance with JIS Z0237) between the dicing film and the die attach film before UV irradiation was sufficiently high, and no defect in dicing accuracy occurred in the dicing step. Besides, when thermocompression bonding was performed on the lead frame substrate after pickup, no conspicuous void that caused a problem in practical use was observed.

The present invention has been described as related to the present embodiments. It is our intention that the present invention not be limited by any of the details of the description unless otherwise specified, but rather be construed broadly within its spirit and scope as set out in the attached claims.

### DESCRIPTION OF SYMBOLS

1 Semiconductor wafer
2 Die attach film (Bonding agent layer)
3 Dicing film
4 Semiconductor chip
5 Semiconductor chip with bonding agent layer
6 Circuit board
7 Bonding wire
8 Sealing resin
9 Semiconductor package

1. A dicing die attach film, comprising:
a dicing film; and
a die attach film laminated on the dicing film,
wherein the die attach film has an arithmetic average roughness Ra1 of from 0.05 to 2.50 μm at a surface in contact with the dicing film, and
wherein a value of ratio of Ra1 to an arithmetic average roughness Ra2 at a surface that is of the die attach film and is opposite to the surface in contact with the dicing film is from 1.05 to 28.00.

2. The dicing die attach film according to claim 1,
wherein the die attach film comprises:
an epoxy resin (A),
an epoxy resin curing agent (B),
a polymer component (C), and
an inorganic filler (D), and
wherein the die attach film is thermally cured to give a cured body having a thermal conductivity of 1.0 W/m·K or more.

3. The dicing die attach film according to claim 1, wherein when the die attach film is heated at a temperature elevation rate of 5° C./min from 25° C., a melt viscosity at 120° C. is in a range of 500 to 10,000 Pa·s.

4. The dicing die attach film according to claim 1, wherein the dicing film is energy ray-curable.

5. A method of producing the dicing die attach film according to claim 1, comprising leveling a surface of the die attach film by using a pressure roll to create a surface state satisfying Ra1 and Ra2.

6. A semiconductor package, comprising:
a semiconductor chip and a circuit board which are bonded to each other with a thermally cured product of a bonding agent; and/or
semiconductor chips which are bonded to each other with a thermally cured product of a bonding agent,
wherein the bonding agent is derived from the die attach film of the dicing die attach film according to claim 1.

7. A method of producing a semiconductor package, comprising the steps of:
a first step of thermocompression bonding the dicing die attach film according to claim 1 to a back surface of a semiconductor wafer where at least one semiconductor circuit is formed on a surface so that the die attach film is in contact with the back surface of the semiconductor wafer;
a second step of integrally dicing the semiconductor wafer and the die attach film to obtain a semiconductor chip with a bonding agent layer on the dicing film, the semiconductor chip with a bonding agent layer including a piece of the die attach film and a semiconductor chip;
a third step of removing the semiconductor chip with a bonding agent layer from the dicing film and thermocompression bonding the semiconductor chip with a bonding agent layer and a circuit board via the bonding agent layer; and
a fourth step of thermally curing the bonding agent layer.
